(19) United States
(12) Patent Application Publication
(10) Pub. No.: US 2010/0003811 A1
(43) Pub. Date: Jan. 7, 2010

(54) METHOD FOR MANUFACTURING EPITAXIAL WAFER

(75) Inventor: Naoyuki WADA, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/497,835

(22) Filed: Jul. 6, 2009

(30) Foreign Application Priority Data
Jul. 7, 2008 (JP) 2008-177314

(51) Int. Cl. H01L 21/20

(52) U.S. Cl. 438/492; 257/E21.09

(57) ABSTRACT

A method for manufacturing an epitaxial wafer is provided, which can alleviate distortions on a back surface of the epitaxial wafer. The method for manufacturing an epitaxial wafer using a susceptor for a vapor phase growth system having a concave shaped wafer placement portion on an upper face thereof, on which a semiconductor wafer is placed, includes: an oxide film forming step in which an oxide film Ox is formed on a back surface of the semiconductor wafer; a wafer placing step in which, after the oxide film forming step, the semiconductor wafer is placed on a wafer placement portion so that the back surface of the semiconductor wafer faces downward; and an epitaxial growth step in which, after the wafer placing step, an epitaxial layer is grown on a main surface of the semiconductor wafer.

The present invention claims benefit of priority to Japanese Patent Application No. 2008-177314 filed on Jul. 7, 2008, the entire disclosure of which is incorporated by reference herein.

### BACKGROUND OF THE INVENTION

1. Field of the Invention

The present invention relates to a method for manufacturing an epitaxial wafer.

2. Related Art

An epitaxial wafer is a semiconductor wafer in which an epitaxial layer is grown on a main surface thereof. Recently, there is a demand for an epitaxial wafer with high flatness and high precision, in accordance with an increase in integration of semiconductor devices and miniaturization of design rule (miniaturized pattern). A vapor phase growth system that grows an epitaxial layer on a main surface of a semiconductor wafer is used for manufacturing an epitaxial wafer.

With the vapor phase growth system, an epitaxial layer can be grown on a main surface of a semiconductor wafer according to the following steps, for example. The semiconductor wafer is placed on a susceptor that is in a reaction container having the disk-shaped susceptor thereinside and into which reactant gas can be supplied. An upper face of the susceptor is a concave shaped wafer placement portion. A semiconductor wafer is placed on the wafer placement portion and heated by a heater disposed on an outer surface of the reaction container, thereby reacting the semiconductor wafer with the reactant gas that passes through the inside of the reaction container. An epitaxial layer is thus grown on the main surface of the semiconductor wafer.

However, in growing of an epitaxial layer on a main surface of the semiconductor wafer, the epitaxial layer tends to be grown in an outer peripheral portion of a back surface of the semiconductor wafer.

In addition, in growing an epitaxial layer on a main surface of the semiconductor wafer, contact trace (sticking) of the susceptor with the back surface of the semiconductor wafer may remain in the outer peripheral portion of the back surface of the semiconductor wafer. Furthermore, sticking and the like, due to difference in thermal expansion of the semiconductor wafer when temperature of the heater rises and falls and when the heater is in a high temperature state, may generate distortions on the back surface of the semiconductor wafer. Moreover, in the outer peripheral portion of the back surface of the semiconductor wafer, in which distortions are particularly prominent, the distortions do not have regularity in orientation. Additionally, there has been a problem of misalignment occurring in photolithography processing, since pattern displacement occurs in a random orientation in thermal processing before the photolithography processing of polycrystalline silicon in a device process, and correction is not possible.

Given this, for example, a method is proposed for evaluating a surface configuration of an epitaxial wafer, as configuration quality thereof, by measuring surface configuration of a main surface and a back surface of the epitaxial wafer along a radial direction thereof, calculating a reference line from a predetermined region in surface configuration data thus measured, and obtaining a local slope representing a difference between the reference line and the surface configuration data in a thickness direction (for example, see Japanese Unexamined Patent Application Publication No. 2006-5164, hereinafter referred to as Patent Document 1, and the like).

However, Patent Document 1 discloses only a method for evaluating the surface configuration of an epitaxial wafer and does not disclose a concrete method for alleviating distortions on a back surface of the epitaxial wafer.

### SUMMARY OF THE INVENTION

Given this, the present invention aims at providing a method for manufacturing an epitaxial wafer that can alleviate distortions on a back surface thereof.

In a first aspect of the present invention, a method for manufacturing an epitaxial wafer using a susceptor for a vapor phase growth system having a concave shaped wafer placement portion on an upper face thereof, on which a semiconductor wafer is placed includes: an oxide film forming step in which an oxide film is formed on a back surface of the semiconductor wafer; a wafer placing step in which, after the oxide film forming step, the semiconductor wafer is placed on the wafer placement portion so that the back surface of the semiconductor wafer faces downward; and an epitaxial growth step in which, after the wafer placing step, an epitaxial layer is grown on a main surface of the semiconductor wafer.

In a second aspect of the present invention, in the oxide film forming step, the oxide film is preferably formed at least in an outer peripheral portion of the back surface of the semiconductor wafer.

In a third aspect of the present invention, the wafer placement portion is preferably composed of a first concave portion that has a circular shape and is concave downward from the upper face of the susceptor, and a second concave portion that is concave downward from a bottom face of the first concave portion and has a circular shape that is concentric with and has a smaller diameter than the first concave portion; a semiconductor wafer supporting portion for supporting the semiconductor wafer on the bottom face of the first concave portion is preferably formed at a position on an outer periphery side of the second concave portion; and in the wafer placing step, the semiconductor wafer is placed on the semiconductor wafer supporting portion so that the outer peripheral portion of the back surface of the semiconductor wafer is supported by the semiconductor wafer supporting portion.

In a fourth aspect of the present invention, in the oxide film forming step, the oxide film is preferably formed on the back surface of the semiconductor wafer by cleaning the back surface of the semiconductor wafer with SC-1 solution.

According to the method for manufacturing an epitaxial wafer of the present invention, distortions on a back surface of an epitaxial wafer can be alleviated.

### BRIEF DESCRIPTION OF THE DRAWINGS

FIG. 1 is a cross-sectional view schematically showing a vapor phase growth system;

FIG. 2 is a cross-sectional view of a susceptor;

FIGS. 3A and 3B are diagrams showing a semiconductor wafer before forming an oxide film on a back surface thereof, in which FIG. 3A is a bottom view and FIG. 3B is a vertical cross-sectional view;

FIGS. 4A and 4B are diagrams showing a semiconductor wafer in which an oxide film is formed on an entire back surface thereof, in which FIG. 4A is a bottom view and FIG. 4B is a vertical cross-sectional view;

FIGS. 5A and 5B are diagrams showing a state where a part of the oxide film is removed from a state shown in FIGS. 4A and 4B, in which FIG. 5A is a bottom view and FIG. 5B is a vertical cross-sectional view;

FIG. 6 is a cross-sectional view showing a state where the semiconductor wafer shown in FIGS. 5A and 5B is placed on a wafer placement portion of the susceptor;

FIG. 7 is a cross-sectional view showing a state where an epitaxial layer is grown from a state shown in FIG. 6;

FIG. 8 is a vertical cross-sectional view of an epitaxial wafer where the oxide film is removed from a state shown in FIG. 7;

FIG. 9 is an evaluation result indicating distortions of a back surface of an epitaxial wafer of Example 1;

FIG. 10 is an evaluation result indicating distortions of a back surface of an epitaxial wafer of Example 2; and

FIG. 11 is an evaluation result indicating distortions of a back surface of an epitaxial wafer of a comparative example.

### DETAILED DESCRIPTION OF THE INVENTION

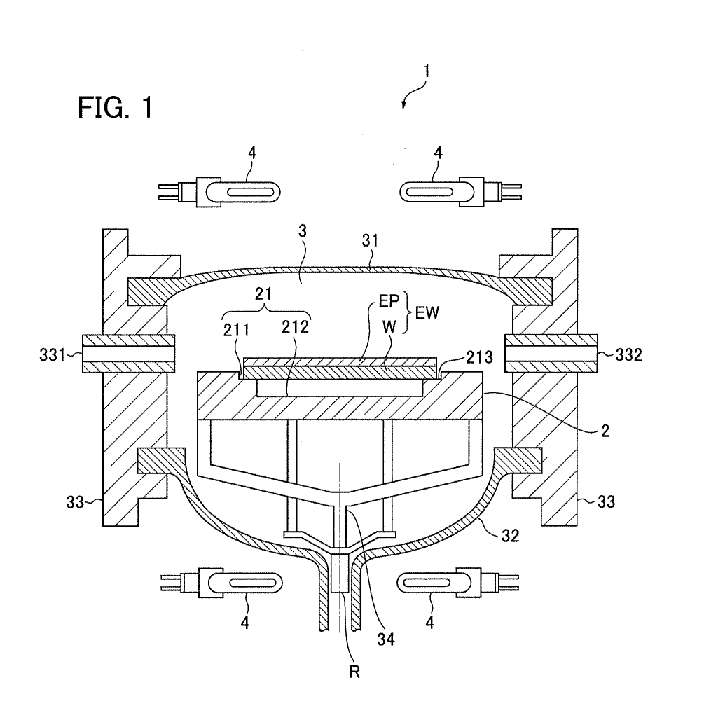

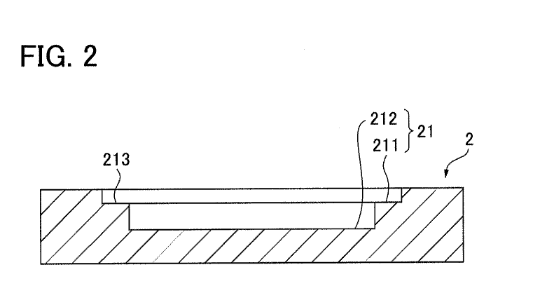

An embodiment of the method for manufacturing an epitaxial wafer according to the present invention is hereinafter described with reference to the drawings. First, a vapor phase growth system used in the embodiment of the method for manufacturing an epitaxial wafer according to the present invention is described. FIG. 1 is a cross-sectional view schematically showing a vapor phase growth system used in the embodiment of the method for manufacturing an epitaxial wafer according to the present invention. FIG. 2 is a cross-sectional view of a susceptor.

### Vapor Phase Growth System

A vapor phase growth system 1 according to the present embodiment is, as shown in FIG. 1, a device for manufacturing an epitaxial wafer EW by vapor-phase growing an epitaxial layer EP on a main surface of a semiconductor wafer W composed of a silicon wafer. The vapor phase growth system 1 includes a susceptor 2, a reaction container 3, and a heating device 4.

The reaction container 3 includes a susceptor 2 thereinside, and is configured so that reactant gas can be supplied thereinto. The reaction container 3 makes the epitaxial layer EP grow on the main surface of the semiconductor wafer W by supplying the reactant gas to the semiconductor wafer W placed on the susceptor 2. The reaction container 3 includes an upper dome 31, a lower dome 32, a dome attaching body 33, and a susceptor supporting portion 34.

The upper dome 31 and the lower dome 32 are composed of a light-permeable member such as quartz.

The dome attaching body 33 is composed of a substantially cylindrical member with upper and lower ends that are open, and supports the upper dome 31 and the lower dome 32 by upper and lower opening portions.

A reactant gas supply pipe 331 is provided on a lateral face of the dome attaching body 33. A reactant gas outlet pipe 332 is provided on a lateral face, which is opposite to the reactant gas supply pipe 331, of the dome attaching body 33. The reactant gas supply pipe 331 and the reactant gas outlet pipe 332 are formed to communicatively connect the inside and the outside of the reaction container 3.

Reactant gas is supplied from the reactant gas supply pipe 331 into the reaction container 3. The reactant gas is obtained by, for example, attenuating a Si source of SiHCl₃ with hydrogen gas and mixing a minute amount of dopant gas therewith. The reactant gas thus supplied passes horizontally through the main surface of the semiconductor wafer W that is placed on the susceptor 2, and then is discharged to the outside of the reaction container 3 through the reactant gas outlet pipe 332.

The susceptor 2 is a member on which the semiconductor wafer W is placed, and disposed inside the reaction container 3. The susceptor 2 is supported at a lower surface thereof by the susceptor supporting portion 34 that is connected with a rotational axis R, and rotated by drive of the rotational axis R. Material of the susceptor 2 is not particularly limited, and may preferably be a carbon substrate coated with a SiC film.

A method for loading and unloading the semiconductor wafer W into and from the susceptor 2 is not particularly limited. The method includes, for example, transferring the semiconductor wafer W using a Bernoulli chuck by moving a carrier jig up and down, transferring the semiconductor wafer W by supporting a lower surface thereof with a pin and moving the pin up and down, and the like.

As shown in FIG. 2, a wafer placement portion 21 that is constituted of a concave portion having a diameter greater than that of the semiconductor wafer W is formed on an upper face of the susceptor 2. The wafer placement portion 21 is constituted of a first concave portion 211 and a second concave portion 212. The first concave portion 211 is a concave portion that has a circular shape and is concave downward from an upper face of the susceptor 2. The second concave portion 212 is a concave portion that is concave downward from a bottom face of the first concave portion 211 and has a circular shape that is concentric with and has a smaller diameter than the first concave portion 211. In addition, in the susceptor 2, a wafer supporting portion 213 for supporting the semiconductor wafer W on the bottom face of the first concave portion 211 is formed at a position on an outer periphery side of the second concave portion 212.

The semiconductor wafer W is placed inside the wafer placement portion 21 while being supported by the wafer supporting portion 213. It should be noted that the wafer supporting portion 213 can be configured to be declivitous from a peripheral side of the first concave portion 211 toward a peripheral side of the second concave portion 212 so as to support the outer peripheral portion of the semiconductor wafer W by line contact, or can be provided unevenly on an upper face of the wafer supporting portion 213 so as to support the outer peripheral portion of the semiconductor wafer W by point contact.

The susceptor supporting portion 34 is composed of a light-permeable member such as quartz. As shown in FIG. 1, the susceptor supporting portion 34 projects toward the inside of the reaction container 3 from a substantially central portion of the lower dome 32 of the reaction container 3 so as to horizontally support the susceptor 2 inside the reaction container 3. In addition, the susceptor supporting portion 34 is, for example, configured to be rotatable around the rotational axis R under control of a control device (not shown).

The heating device 4 is provided on each of upper and lower sides of the reaction container 3. The heating device 4 heats the susceptor 2 and the semiconductor wafer W placed thereon by radiative heat via the upper dome 31 and the lower dome 32 of the reaction container 3, thereby setting the semiconductor wafer W to a predetermined temperature. For example, a halogen lamp, an infrared lamp and the like can be adopted as the heating device 4. In addition to radiative heating, a radio-frequency heating system that heats the semiconductor wafer W by induction heating can be adopted for the heating device 4.

### Method for Manufacturing Epitaxial Wafer

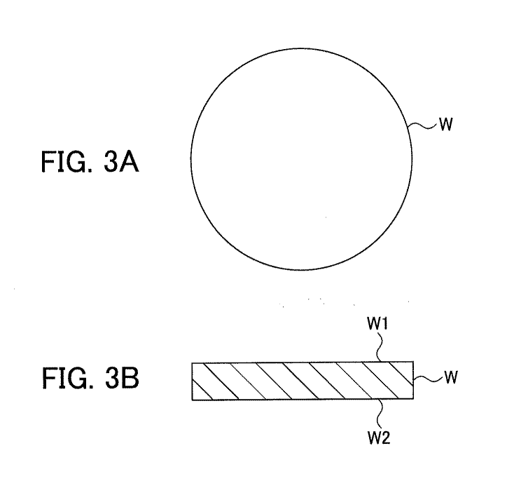

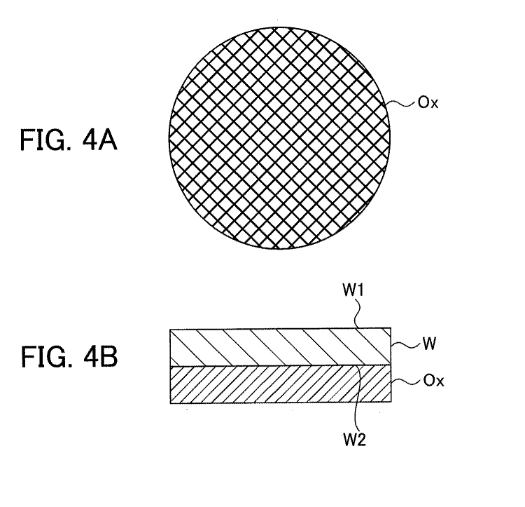

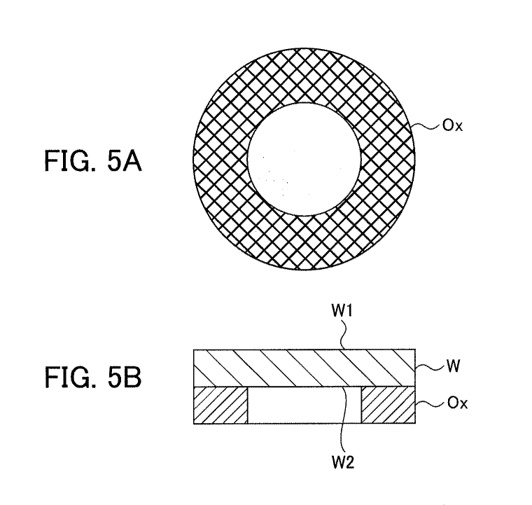

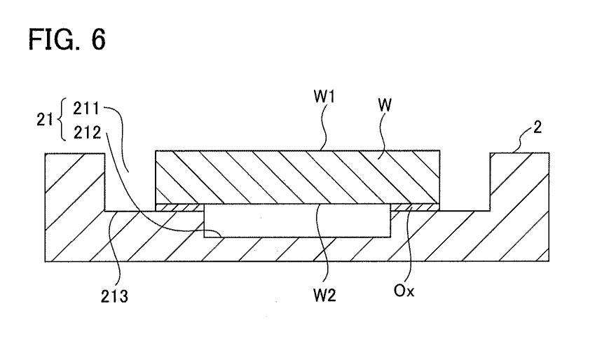

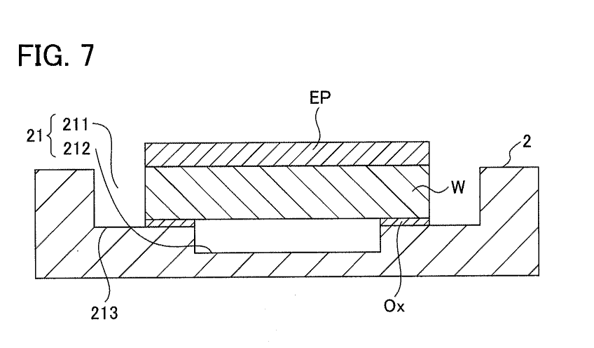

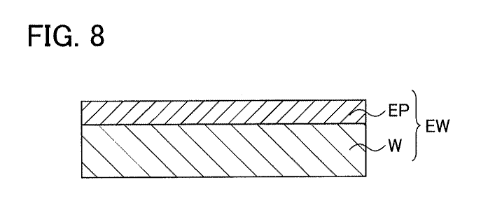

An embodiment of the method for manufacturing an epitaxial wafer according to the present invention is hereinafter described. FIGS. 3A and 3B are diagrams showing the semiconductor wafer W before forming an oxide film on a back surface W2 thereof, in which FIG. 3A is a bottom view and FIG. 3B is a vertical cross-sectional view. FIGS. 4A and 4B are diagrams showing the semiconductor wafer W in which an oxide film Ox is formed on an entirety of the back surface W2 thereof, in which FIG. 4A is a bottom view and FIG. 4B is a vertical cross-sectional view. FIGS. 5A and 5B are diagrams showing a state where a part of the oxide film Ox is removed from a state shown in FIGS. 4A and 4B, in which FIG. 5A is a bottom view and FIG. 5B is a vertical cross-sectional view. FIG. 6 is a cross-sectional view showing a state where the semiconductor wafer W shown in FIGS. 5A and 5B is placed on the wafer placement portion 21 of the susceptor 2. FIG. 7 is a cross-sectional view showing a state where an epitaxial layer EP is grown. FIG. 8 is a vertical cross-sectional view of an epitaxial wafer where the oxide film Ox is removed.

A method for manufacturing an epitaxial wafer according to the present embodiment is performed using the abovementioned vapor phase growth system 1. The method for manufacturing an epitaxial wafer according to the present embodiment includes: an oxide film forming step in which an oxide film Ox is formed on a back surface W2 of the semiconductor wafer W; a wafer placing step in which, after the oxide film forming step, the semiconductor wafer W is placed on the wafer placement portion 21 so that the back surface W2 of the semiconductor wafer W faces downward; and an epitaxial growth step in which, after the wafer placing step, an epitaxial layer EP is grown on a main surface W1 of the semiconductor wafer W.

In the present embodiment, the semiconductor wafer W having a predetermined thickness is formed by slicing a silicon single crystal ingot, before the oxide film forming step. Diameter of the semiconductor wafer W is, for example, 200 mm, 300 mm, or 450 mm. Surfaces of the semiconductor wafer W thus sliced are etched, and then the main surface W1 and the back surface W2 of the semiconductor wafer W are mirror-finished. Thereafter, the oxide film forming step, the wafer placing step, and the epitaxial growth step are performed.

### Oxide Film Forming Step

The oxide film forming step is a step for forming an oxide film Ox on a back surface W2 of the semiconductor wafer W. More specifically, the back surface W2 of the semiconductor wafer W as shown in FIGS. 3A and 3B is cleaned using cleaning solution and the oxide film Ox is formed on the entire back surface W2 of the semiconductor wafer W as shown in FIGS. 4A and 4B. After forming the oxide film Ox on the entire back surface W2 of the semiconductor wafer W, a region in which the oxide film Ox is not formed is provided as shown in FIGS. 5A and 5B, by removing the oxide film Ox in a region excepting the outer peripheral portion of the semiconductor wafer W that is in contact with the wafer supporting portion 213.

A region in which the oxide film Ox is formed is, more specifically, a region of at least 5 mm from an outer end of the semiconductor wafer W. It should be noted that, on the back surface W2 of the semiconductor wafer W, the oxide film Ox in a part corresponding to a lift pin portion (not shown) must be removed. In addition, in a chamfered portion on the main surface W1 of the outer peripheral portion of the semiconductor wafer W, the oxide film Ox is removed. The diameter of the region in which the oxide film Ox is not formed is preferably no less than 80% of the diameter of the semiconductor wafer W and more preferably 290 mm. In addition, the oxide film Ox is preferably not formed in a chamfered portion of the main surface W1 and the back surface W2 of the outer peripheral portion of the semiconductor wafer W. In other words, the oxide film Ox is preferably formed only in the outer peripheral portion of the back surface W2 of the semiconductor wafer W.

It is preferable to provide a region in which the oxide film Ox is not formed in the following situations.

The oxide film Ox may be locally etched by inflow of process gas to the back surface W2 of the semiconductor wafer W, thereby resulting in deterioration of flatness. Therefore the oxide film Ox is preferably not formed particularly in a region corresponding to the abovementioned lift pin portion and the like for moving the semiconductor wafer W up and down. In addition, if the oxide film Ox is formed in the chamfered portion of the semiconductor wafer W, radiation from a lateral face may be different and temperature balance in the outer peripheral portion of the semiconductor wafer W may be lost, thereby generating slip. Therefore the oxide film Ox is preferably not formed in the chamfered portion of the semiconductor wafer W.

The oxide film Ox is formed by cleaning the back surface W2 of the semiconductor wafer W with cleaning solution, using batch cleaning equipment, single wafer processing cleaner and the like. After cleaning the back surface W2 of the semiconductor wafer W with cleaning solution, the oxide film Ox formed by the cleaning solution remains thereon.

The cleaning solution for forming the oxide film Ox is not particularly limited as long as the cleaning solution can form the oxide film Ox on the back surface W2 of the semiconductor wafer W. Such a cleaning solution includes well-known cleaning solutions such as SC (Standard Cleaning)-1 solution, SC-2 solution, ozone water, HF-HNO₃ solution, HF-H₂O₂ solution and the like. These can be used singly or in combination. It should be noted that the SC-1 solution is a mixed liquid in which NH₄OH, H₂O₂, and H₂O are mixed in a proportion of 1:1:5. On the other hand, the SC-2 solution is a mixed liquid in which HCl, H₂O₂, and H₂O are mixed in a proportion of 1:1:5.

The thickness of the oxide film Ox is preferably 5 to 30 Å. The oxide film Ox less than 5 Å in thickness may be unable to alleviate distortions on the back surface W2 of the epitaxial wafer EW. On the other hand, if the thickness of the oxide film Ox exceeds 30 Å, it may be difficult to remove the oxide film Ox after the epitaxial growth step (described later).

In addition, the internal temperature of a cleaning apparatus in cleaning of the semiconductor wafer W is preferably an ambient temperature up to 90° C.

Thickness of the oxide film Ox can be appropriately changed by adjusting concentration of the cleaning solution, cleaning time, temperature of the cleaning solution and the like.

### Wafer Placing Step

The wafer placing step is performed after the oxide film forming step. More specifically, after forming the oxide film Ox on the back surface W2 of the semiconductor wafer W, the semiconductor wafer W is placed on the wafer placement portion 21 so that the back surface W2 of the semiconductor wafer W faces downward as shown in FIG. 6. In other words, the semiconductor wafer W is placed on the wafer placement portion 21 so that the oxide film Ox is in contact with the wafer supporting portion 213.

A method for placing the semiconductor wafer W on the wafer placement portion 21 is not particularly limited and various well-known methods can be adopted for placing the semiconductor wafer W.

### Epitaxial Growth Step

The epitaxial growth step is performed after the wafer placing step. Epitaxial growth is performed by introducing reactant gas from the reactant gas supply pipe 331 to the inside of the reaction container 3, thereby growing silicon produced by pyrolysis or reduction of the reactant gas at a reaction rate of 0.5 to 6.0 μm/min on the main surface W1 of the semiconductor wafer W heated to high temperature of 1000 to 1200° C. The reactant gas is obtained, for example, by mixing SiHCl₃, which is Si source, with hydrogen gas. In addition, dopant gas can be mixed therewith as necessary.

As a result, as shown in FIG. 7, the epitaxial layer EP is grown on the main surface W1 of the semiconductor wafer W and the epitaxial wafer EW can be obtained.

After the epitaxial growth step, the next step is performed in a state where the oxide film Ox remains in the outer peripheral portion of the back surface W2 of the epitaxial wafer EW. Alternatively, after the epitaxial growth step, the oxide film Ox on the back surface W2 of the epitaxial wafer EW can be removed by cleaning using HF solution, BHF solution, DHF solution and the like. The epitaxial wafer EW without the oxide film Ox is thus manufactured as shown in FIG. 8.

An embodiment of the present invention has been described in detail with reference to the drawings; however, the present invention is not limited thereto and can be changed and implemented accordingly within a scope of the objective of the present invention.

For example, in the abovementioned embodiment, the oxide film Ox is formed in the outer peripheral portion of the back surface W2 of the semiconductor wafer W; however, the present invention is not limited thereto and the semiconductor wafer W can be placed on the wafer placement portion 21 in a state where the oxide film Ox is formed on the entire back surface W2 of the semiconductor wafer W, without removing the oxide film Ox from the back surface W2 of the semiconductor wafer W, and epitaxial growth can be performed.

In addition, for example, the wafer placement portion 21 of the susceptor 2 is not required to have the second concave portion 212. In other words, the wafer placement portion 21 can be a single-level concave portion.

### EXAMPLES

The present invention is described in further detail hereinafter by means of examples; however, the present invention is not limited thereto.

### Example 1

A mirror-finished semiconductor wafer W of 300 mm in diameter was set on a single wafer processing cleaner and cleaned for 60 seconds by spraying SC-1 solution on a back surface of the semiconductor wafer W. After cleaning, an oxide film Ox of 10 Å in thickness was formed on the entire back surface W2 of the semiconductor wafer W.

The oxide film Ox in a region other than an outer peripheral portion of the back surface W2 of the semiconductor wafer W was removed with HF solution. The diameter of a region in which the oxide film Ox is not formed was 290 mm.

Next, the semiconductor wafer W was placed on the wafer placement portion 21 so that the back surface W2 of the semiconductor wafer W on which the oxide film Ox was formed faces downward.

Reactant gas obtained by mixing SiHCl₃, hydrogen gas, and dopant gas was introduced to the inside of a reaction container 3 through a reactant gas supply pipe 331. The semiconductor wafer W was heated to 1130° C. and an epitaxial layer EP was grown at a reaction rate of 2.5 μm/min.

After growing the epitaxial layer EP, the oxide film Ox on a back surface W2 of the semiconductor wafer W was cleaned with HF solution thereby removing the oxide film Ox.

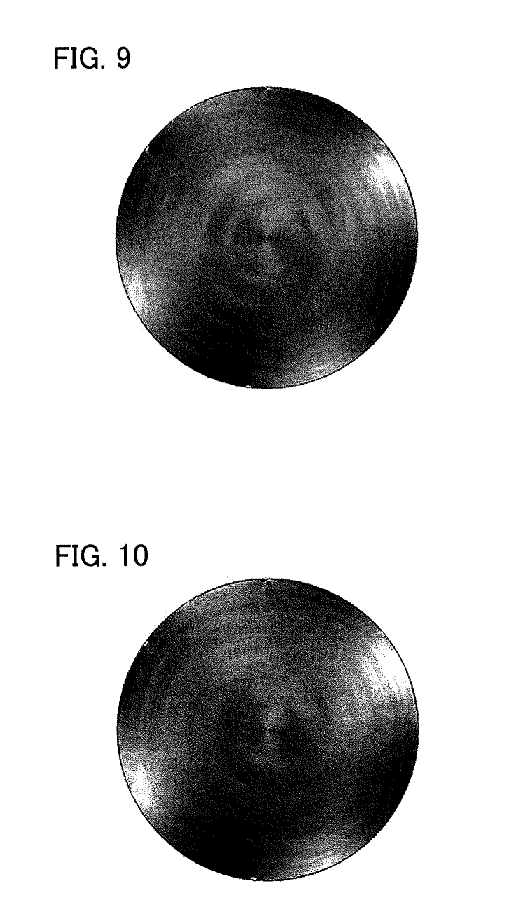

Regarding an epitaxial wafer from which the oxide film Ox was removed, distortions on the back surface W2 of the epitaxial wafer EW were measured using SIRD (Scanning InfraRed Depolarization) (SIRD A300 manufactured by PVA TePla AG). As a result, distortions were found to be reduced as shown in FIG. 9.

### Example 2

An epitaxial wafer was manufactured in the same process as in Example 1, except for the oxide film Ox being formed on the entire back surface W2 of the semiconductor wafer W. Distortions on the back surface W2 of the epitaxial wafer EW of Example 2 were measured. As a result, distortions were found to be reduced as shown in FIG. 10.

### Comparative Example

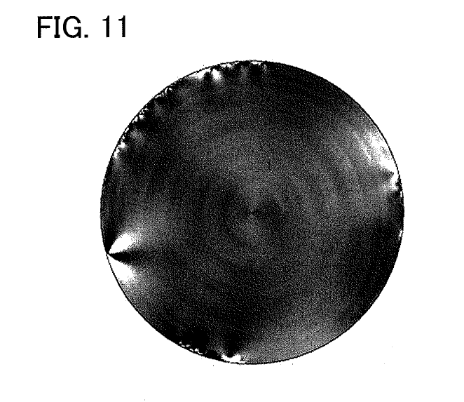

An epitaxial wafer was manufactured in the same process as in Example 1, except for the oxide film Ox not being formed on the back surface W2 of the semiconductor wafer W as shown in FIGS. 3A and 3B. Distortions on the back surface W2 of the epitaxial wafer EW of a Comparative Example were measured. As a result, distortions were found to be generated as shown in FIG. 11.

As shown in FIG. 11, epitaxial growth without forming the oxide film Ox on the back surface W2 of the semiconductor wafer W is found to generate many distortions on an outer periphery side of the back surface W2 of the semiconductor wafer W. On the other hand, as shown in FIGS. 9 and 10, epitaxial growth after forming the oxide film Ox on the back surface W2 of the semiconductor wafer W is found to reduce distortions on the outer periphery side of the back surface W2 of the semiconductor wafer W.

What is claimed is:

1. A method for manufacturing an epitaxial wafer using a susceptor for a vapor phase growth system having a concave shaped wafer placement portion on an upper face thereof, on which a semiconductor wafer is placed, the method comprising:
an oxide film forming step in which an oxide film is formed on a back surface of the semiconductor wafer;
a wafer placing step in which, after the oxide film forming step, the semiconductor wafer is placed on the wafer placement portion so that the back surface of the semiconductor wafer faces downward; and
an epitaxial growth step in which, after the wafer placing step, an epitaxial layer is grown on a main surface of the semiconductor wafer.

2. The method for manufacturing the epitaxial wafer according to claim 1, wherein in the oxide film forming step the oxide film is formed at least in an outer peripheral portion of the back surface of the semiconductor wafer.

3. The method for manufacturing the epitaxial wafer according to claim 1, wherein: the wafer placement portion is composed of a first concave portion that has a circular shape and is concave downward from the upper face of the susceptor, and a second concave portion that is concave downward from a bottom face of the first concave portion and has a circular shape that is concentric with and has a smaller diameter than the first concave portion;
a semiconductor wafer supporting portion for supporting the semiconductor wafer on the bottom face of the first concave portion is formed at a position on an outer periphery side of the second concave portion; and
in the wafer placing step, the semiconductor wafer is placed on the semiconductor wafer supporting portion so that the outer peripheral portion of the back surface of the semiconductor wafer is supported by the semiconductor wafer supporting portion.

4. The method for manufacturing the epitaxial wafer according to claim 2, wherein: the wafer placement portion is composed of a first concave portion that has a circular shape and is concave downward from the upper face of the susceptor, and a second concave portion that is concave downward from a bottom face of the first concave portion and has a circular shape that is concentric with and has a smaller diameter than the first concave portion;
a semiconductor wafer supporting portion for supporting the semiconductor wafer on the bottom face of the first concave portion is formed at a position on an outer periphery side of the second concave portion; and
in the wafer placing step, the semiconductor wafer is placed on the semiconductor wafer supporting portion so that the outer peripheral portion of the back surface of the semiconductor wafer is supported by the semiconductor wafer supporting portion.

5. The method for manufacturing the epitaxial wafer according to claim 1, wherein: in the oxide film forming step, the oxide film is formed on the back surface of the semiconductor wafer by cleaning the back surface of the semiconductor wafer with SC-1 solution.

6. The method for manufacturing the epitaxial wafer according to claim 2, wherein: in the oxide film forming step, the oxide film is formed on the back surface of the semiconductor wafer by cleaning the back surface of the semiconductor wafer with SC-1 solution.

7. The method for manufacturing the epitaxial wafer according to claim 3, wherein: in the oxide film forming step, the oxide film is formed on the back surface of the semiconductor wafer by cleaning the back surface of the semiconductor wafer with SC-1 solution.

8. The method for manufacturing the epitaxial wafer according to claim 4, wherein: in the oxide film forming step, the oxide film is formed on the back surface of the semiconductor wafer by cleaning the back surface of the semiconductor wafer with SC-1 solution.
